(19) United States
(12) Patent Application Publication
(10) Pub. No.: US 2014/0035157 A1
(43) Pub. Date: Feb. 6, 2014

(54) SEMICONDUCTOR PACKAGE, MANUFACTURING METHOD THEREOF, AND SEMICONDUCTOR PACKAGE MANUFACTURING MOLD

(71) Applicant: SAMSUNG ELECTRO-MECHANICS CO., LTD., Suwon (KR)

(72) Inventors: Si Joong YANG, Suwon (KR); Joon Seok CHAE, Suwon (KR); Tae Hyun KIM, Suwon (KR); Suk Ho LEE, Suwon (KR)

(73) Assignee: SAMSUNG ELECTRO-MECHANICS CO., LTD., Suwon (KR)

(21) Appl. No.: 13/688,430

(22) Filed: Nov. 29, 2012

(30) Foreign Application Priority Data
Jul. 31, 2012 (KR) 10-2012-0084153

(51) Int. Cl. H01L 23/48; H01L 21/56

(52) U.S. Cl. CPC H01L 23/481; H01L 21/565
USPC 257/774; 438/123; 425/123

(57) ABSTRACT

There is provided a semiconductor package including: at least one internal lead having at least one electronic component mounted on a surface thereof; a molding unit sealing the electronic component and the internal lead; at least one external lead extending from the internal lead and protruding outwardly from ends of the molding unit; and a stopper provided on the external lead.

### CROSS-REFERENCE TO RELATED APPLICATIONS

This application claims the priority of Korean Patent Application No. 10-2012-0084153 filed on Jul. 31, 2012, in the Korean Intellectual Property Office, the disclosure of which is incorporated herein by reference.

### BACKGROUND OF THE INVENTION

1. Field of the Invention

The present invention relates to a semiconductor package, a manufacturing method thereof, and a semiconductor package manufacturing mold, and more particularly, to a semiconductor package in which a stopper is formed to maintain a space between an external substrate and the semiconductor package, a manufacturing method thereof, and a semiconductor package manufacturing mold.

2. Description of the Related Art

In general, a semiconductor package includes a lead frame, a power semiconductor device mounted on the lead frame, and a molding unit for molding the exterior of each device with resin.

Such a semiconductor package is mounted on an external substrate by inserting an external lead protruding outwardly from the semiconductor package into a through hole of the external substrate and performing soldering thereon.

In this regard, a predetermined space should be maintained between the semiconductor package and the external substrate in order to secure an insulation distance and prevent short-circuits.

Patent Document 1, described in the related art document below, discloses a semiconductor package in which a space between the semiconductor package and a substrate is adjusted by tapering external leads disposed on both ends of the substrate.

However, maintaining the predetermined space by using only the external leads disposed on both ends of the substrate, among a plurality of external leads, is problematic in terms of the fixation of the semiconductor package, and is also problematic in that an additional process of forming the external leads to be tapered is necessary.

### RELATED ART DOCUMENT

(Patent Document 1) Korean Patent Laid-Open Publication No. 2010-0005654

### SUMMARY OF THE INVENTION

An aspect of the present invention provides a semiconductor package capable of implementing stoppers on external leads without restrictions on spaces and thicknesses thereof, and simplifying a process of forming the stoppers in the semiconductor package by forming the stoppers of the same materials as a molding unit, a manufacturing method thereof, and a semiconductor package manufacturing mold.

According to an aspect of the present invention, there is provided a semiconductor package including: at least one internal lead having at least one electronic component mounted on a surface thereof; a molding unit sealing the electronic component and the internal lead; at least one external lead extending from the internal lead and protruding outwardly from ends of the molding unit; and a stopper provided on the external lead.

The external lead may have a through hole passing through one surface and the other surface thereof.

The stopper may fill the through hole and be provided on at least one of one surface and the other surface of the external lead.

The stopper may be formed to surround a remainder of the external lead with the exception of a portion thereof mounted in an external substrate.

The stopper may be formed of the same material as the molding unit.

The stopper may be formed of one of a silicon gel, an epoxy molding compound (EMC), and polyimide.

The stopper may connect at least two of the external leads.

According to another aspect of the present invention, there is provided a method of manufacturing a semiconductor package, the method including: mounting an electronic component on one surface of an internal lead of a lead frame; placing the lead frame on which the electronic component is mounted in a mold; forming a molding unit by injecting molding resin into the mold such that the electronic component and the internal lead are sealed and an external lead extending from the internal lead is exposed to the outside; and forming a stopper on the external lead such that a predetermined space is maintained between the external lead and a substrate into which the external lead is inserted.

The forming of the molding unit may include injecting the molding resin into a first cavity provided in the mold; and hardening the molding resin injected into the first cavity.

The forming of the stopper may be simultaneously performed with the forming of the molding unit.

The forming of the stopper on the external lead may be performed by placing the external lead in a second cavity provided in the mold and injecting the molding resin into the second cavity.

The injecting of the molding resin into the second cavity may be performed via a second inflow path that connects the first cavity and the second cavity.

According to another aspect of the present invention, there is provided a first cavity in which an internal lead having an electronic component mounted thereon is disposed; a second cavity in which an external lead extending from the internal lead is disposed; a first inflow path connected to the first cavity so that molding resin is injected into the first cavity; and a second inflow path connecting the first cavity and the second cavity.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a plan view of a semiconductor package according to an embodiment of the present invention;

FIG. 2 is an enlarged plan view of part A of FIG. 1;

FIG. 3 is a cross-sectional view of line B-B′ of FIG. 1;

FIG. 4 is a side sectional view of an external lead showing an example of a stopper according to an embodiment of the present invention;

FIG. 5 is a plan view of an external lead showing an example of a stopper according to an embodiment of the present invention;

FIG. 6 is a side sectional view of an external lead showing a stopper disposed in a through hole formed in the external lead according to an embodiment of the present invention;

FIG. 7 is a side sectional view of an external lead showing a stopper disposed in a through hole formed in the external lead according to an embodiment of the present invention;

FIG. 8 is a plan view of an external lead showing an example of a stopper according to an embodiment of the present invention;

FIG. 9 is a rear view of an external lead showing a stopper disposed in a through hole formed in the external lead according to an embodiment of the present invention;

FIG. 10 is a plan view of an external lead showing a stopper formed in a remainder of the external lead with the exception of a portion thereof inserted into an external substrate according to an embodiment of the present invention;

FIG. 11 is a schematic plan view of a mold for manufacturing a semiconductor package according to an embodiment of the present invention; and

FIG. 12 is a schematic plan view of a semiconductor package disposed in a mold for manufacturing the semiconductor package according to an embodiment of the present invention.

### DETAILED DESCRIPTION OF THE EMBODIMENTS

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

To define terms regarding directions, an outward direction or an inward direction may be a direction toward an outer edge of a molding unit 120 from the center of the molding unit 120 or vice versa.

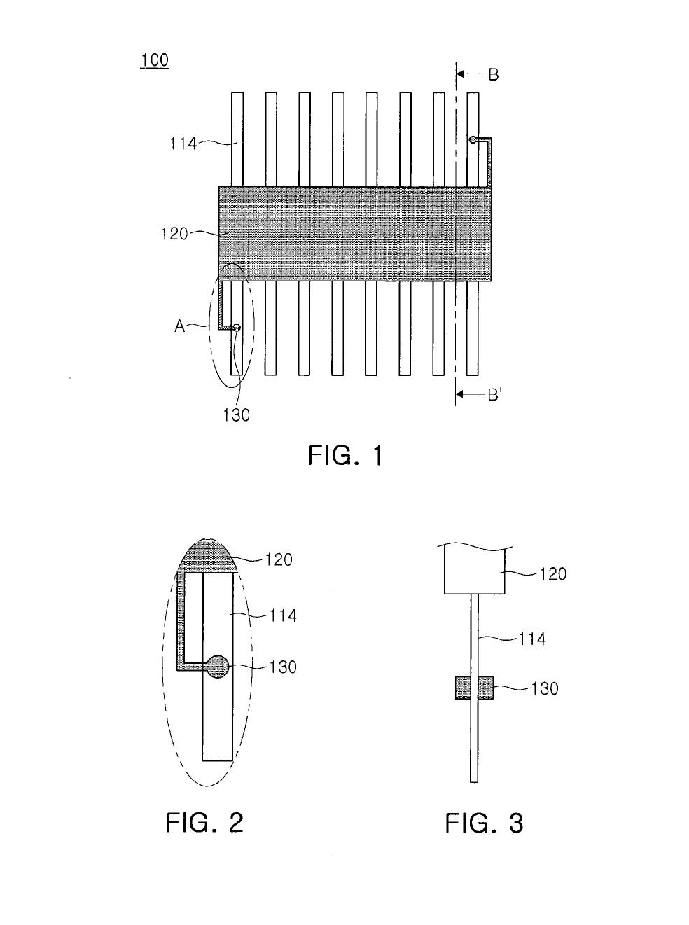

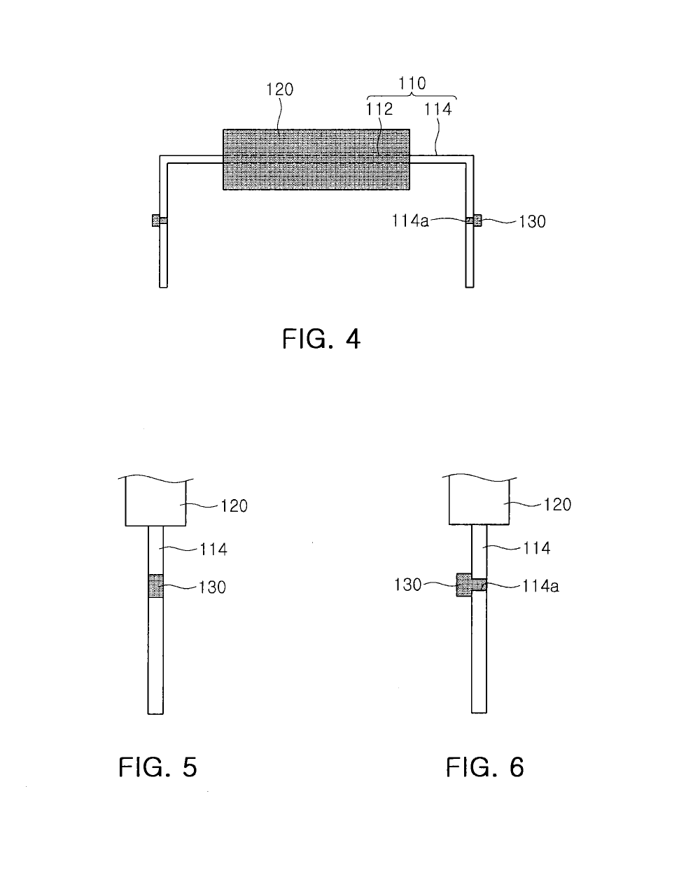

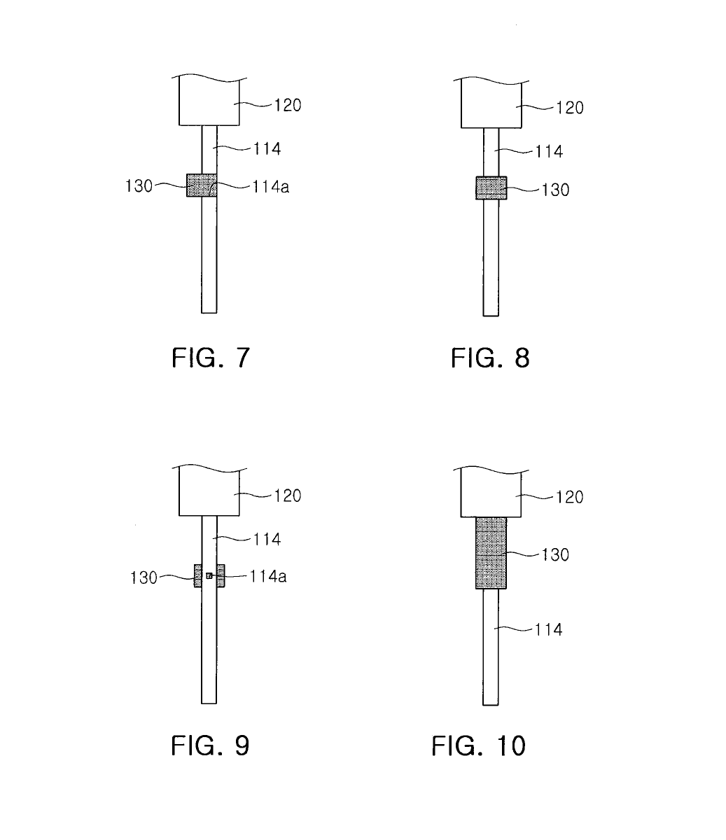

FIG. 1 is a plan view of a semiconductor package according to an embodiment of the present invention. FIG. 2 is an enlarged plan view of part A of FIG. 1. FIG. 3 is a cross-sectional view of line B-B′ of FIG. 1. FIG. 4 is a side sectional view of an external lead showing an example of a stopper according to an embodiment of the present invention. FIG. 5 is a plan view of an external lead showing an example of a stopper according to an embodiment of the present invention. FIG. 6 is a side sectional view of an external lead showing a stopper disposed in a through hole formed in the external lead according to an embodiment of the present invention. FIG. 7 is a side sectional view of an external lead showing a stopper disposed in a through hole formed in the external lead according to an embodiment of the present invention. FIG. 8 is a plan view of an external lead showing an example of a stopper according to an embodiment of the present invention. FIG. 9 is a rear view of an external lead showing a stopper disposed in a through hole formed in the external lead according to an embodiment of the present invention. FIG. 10 is a plan view of an external lead showing a stopper formed in a remainder of the external lead with the exception of a portion thereof inserted into an external substrate according to an embodiment of the present invention.

Referring to FIGS. 1 through 10, a semiconductor package 100 according to an embodiment of the present invention may include electronic components (not shown), a lead frame 110, the molding unit 120, and a stopper 130.

The electronic components may include various electronic devices such as a passive device, an active device, and the like. Electronic devices that may be mounted on the lead frame 110 or may be embedded in the lead frame 110 may be used as the electronic components.

That is, the electronic components according to an embodiment of the present invention may include at least one active device such as a semiconductor chip and various passive devices.

Meanwhile, the semiconductor chip may be electrically connected to the lead frame 110 through a bonding wire.

The bonding wire may be formed of metal, for example, aluminum (Al), gold (Au), or an alloy thereof.

However, the present invention is not limited thereto but various applications may be possible, such as the semiconductor chip being electrically connected to the lead frame 110 through flip chip bonding by manufacturing the semiconductor chip in a flip chip scheme as occasion demands.

The lead frame 110 includes a plurality of leads. In this regard, each lead may include an external lead 114 connected to an external substrate (not shown) and an internal lead 112 connected to the electronic component.

That is, the external lead 114 may refer to a part of the lead exposed to the outside of the molding unit 120 to be described later, and the internal lead 112 may refer to a part of the lead disposed inside the molding unit 120.

In this regard, the external lead 114 may protrude toward ends of the molding unit 120, and may be formed to be curved, extending from a protruding one end.

The electronic components (not shown) may be mounted on one surface of the internal lead 112, and may be electrically connected to the internal lead 112 through the bonding wire.

Electrodes for mounting the electronic components (not shown) or a circuit pattern (not shown) for electrically connecting the mounting electrodes may be formed on a top surface of the lead frame 110.

The molding unit 120 is provided between the electronic components (not shown) mounted on the internal lead 112, thereby preventing electrical short-circuits therebetween, as well as the molding unit 120 surrounding the electronic components from the outside to fix the electronic components, thereby safely protecting the electronic components from external impacts.

More specifically, the molding unit 120 may seal a part of the lead frame 110 and the electronic components.

The molding unit 120 may be formed to cover and seal the electronic components and the internal lead 112 of the lead frame 120 connected to the electronic components and protect the electronic components from the surrounding environment.

Also, the molding unit 120 surrounds the electronic components from the outside to fix the electronic components, thereby protecting the electronic components from external impacts.

The molding unit 120 may be formed through a molding process. In this case, a silicon gel, an epoxy molding compound (EMC), polyimide, or the like, having high thermal conductivity, may be used as materials for the molding unit 120.

However, the materials for the molding unit 120 are not limited thereto. Any insulation materials may be used as materials for the molding unit 120.

When the external lead 114 is mounted on an external substrate (not shown), the stopper 130 may protrude from at least one surface of the external lead 114 such that a predetermined space may be maintained between the semiconductor package 100 according to the present invention and the external substrate.

That is, when the external lead 114 is inserted into the external substrate, an insertion distance may be limited by the stopper 130.

Thus, the stopper 130 may allow a desired spacing to be maintained between the external lead 114 and the external substrate.

In this regard, the stopper 130 may be formed on both one surface and the other surface of the external lead 114, or may be formed on either one surface or the other surface thereof.

A method of allowing the stopper 130 to be disposed on the external lead 114 will be described later.

Meanwhile, a through hole 114a passing through one surface and the other surface of the external lead 114 may be formed in the external lead 114.

In a case in which the stopper 130 fills the through hole 114a and is provided on at least one of one surface and the other surface of the external lead 114, a contact surface between the stopper 130 and the external lead 114 increases, and thus the stopper 130 may be securely attached to the external lead 114.

In this regard, the stopper 130 may be formed to have a variety of shapes such as a circular shape, a triangular shape, a star shape, or an oval shape, and the technical idea of the present invention is not limited by the shape of the stopper 130.

The stopper 130 may be formed through the molding process likewise the molding unit 120. In this case, a silicon gel, an EMC, polyimide, or the like, having high thermal conductivity, may be used as materials for the stopper 130.

However, the materials for the stopper 130 are not limited thereto. Any insulation materials may be used as the materials for the stopper 130.

That is, the stopper 130 may be formed of the same material as that of the molding unit 120.

Since the stopper 130 is formed of the same material as that of the molding unit 120, even if spaces between the plurality of the external leads 114 are dense, insulation characteristics may be secured and short-circuits between the plurality of external leads 114 may be prevented.

In this regard, the stopper 130 may be disposed on each of the plurality of external leads 114, and may be disposed to connect the plurality of external leads 114.

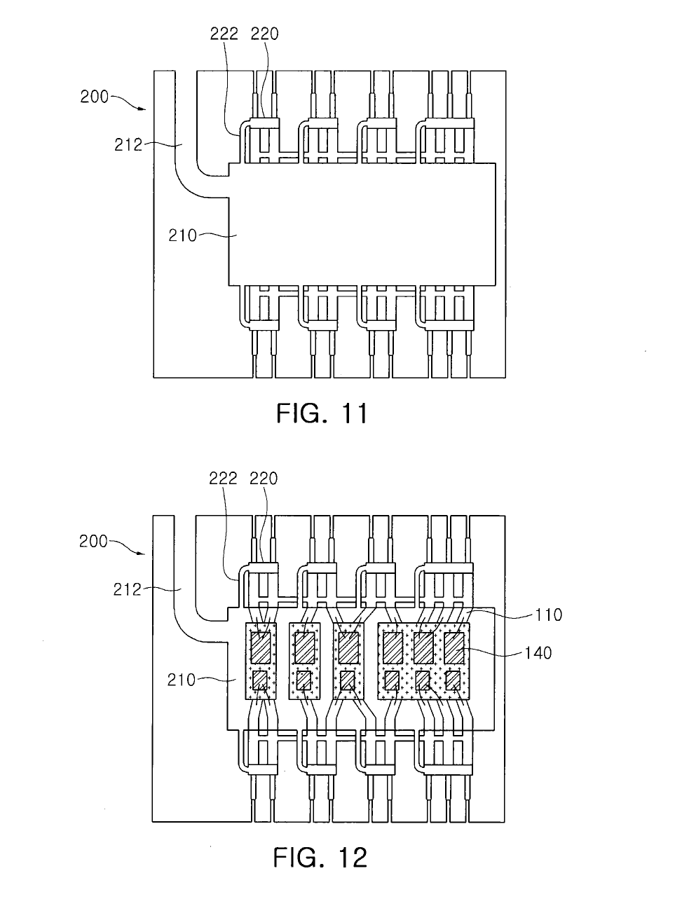

FIG. 11 is a schematic plan view of a mold for manufacturing a semiconductor package according to an embodiment of the present invention. FIG. 12 is a schematic plan view of a semiconductor package disposed in a mold for manufacturing the semiconductor package according to an embodiment of the present invention.

A method of manufacturing the semiconductor package 100 and a mold for the semiconductor package 100 according to an embodiment of the present invention will now be described with reference to FIGS. 11 and 12 below.

The construction of the semiconductor package 100 described above will be further clarified from the following description of the method of manufacturing the semiconductor package 100.

In the method of manufacturing the semiconductor package 100 according to the embodiment of the present invention, an electronic component 140 may be first mounted on one surface of the lead frame 110.

More specifically, the electronic component 140 is mounted on the internal lead 112 included in the lead frame 110, and the lead frame 110 in which the electronic component is mounted is disposed in a mold 200 for performing a molding process.

That is, the mold 200 may be the mold for manufacturing the semiconductor package 100 according to the embodiment of the present invention. The mold 200 may be included as a single member, or may include an upper mold portion and a lower mold portion so that the upper mold portion and the lower mold portion are combined with each other.

Molding resin is injected into the mold 200 so that the internal lead 112 including the electronic component 140 is sealed and the external lead 114 extending from the internal lead 112 is exposed to the outside. The molding resin injected into the mold 200 is hardened to form the molding unit 120.

In this regard, a first cavity 210 is included in the mold 200 so as to form the molding unit 120.

That is, a space in which the molding unit 120 is formed is partitioned by the first cavity 210.

Also, the mold 200 may include a first inflow path 212 in which the molding resin injected from the outside moves to the first cavity 210.

Also, the mold 200 may include a second cavity 220 used to form the stopper 130 on the external lead 114, and may include a second inflow path 222 that connects the first cavity 210 and the second cavity 220 so that the first cavity 210 and the second cavity 220 are connected to each other.

In a case in which the molding resin flows into the mold 200 from the outside, the molding resin may be injected into the first cavity 210 through the first inflow path 212, and the molding resin injected into the first cavity 210 may be injected into the second cavity 220 through the second inflow path 222.

In this regard, the second cavity 220 may have a variety of shapes according to a desired shape of the stopper 130.

That is, the second cavity 220 may be disposed to surround one surface of the external lead 114, may be disposed to surround both one surface and the other surface of the external lead 114, or may be disposed to surround the plurality of the external leads 114.

Also, the second cavity 220 may be formed to surround a remainder of the external lead 114 with the exception of a portion thereof mounted in an external substrate (not shown).

The molding resin flows into the second cavity 220 through the second inflow path 222, and thus the molding unit 120 and the stopper 130 may be formed simultaneously.

After the molding process is completely performed, the mold 200 is removed and the remainder of the molding resin, with the exception of the molding unit 120 and the stopper 130, is cut, and thus the semiconductor package 100 according to the embodiment of the present invention is completely manufactured.

According to the above-described process, the material of the stopper 130 may be the same as the material of the molding unit 120.

Also, the stopper 130 is implemented in the molding process, as the semiconductor package 100 becomes smaller, even if spaces between the external leads 114 are dense, the stopper 130 may be easily implemented without limitations on spaces between the external leads 114.

Also, the stopper 130 may be simultaneously formed on the external lead 114 during the molding process of forming the molding unit 120, thereby reducing an operation time and simplifying an operation process.

As set forth above, in a semiconductor package, a manufacturing method thereof, and a semiconductor package manufacturing mold according to embodiments of the invention, stoppers can be implemented in external leads without restrictions on spaces and thicknesses of the external leads, and a process of forming the stoppers in the semiconductor package can be simplified by forming the stoppers made of the same material as that of a molding unit.

While the present invention has been shown and described in connection with the embodiments, it will be apparent to those skilled in the art that modifications and variations can be made without departing from the spirit and scope of the invention as defined by the appended claims.

What is claimed is:

1. A semiconductor package comprising:
at least one internal lead having at least one electronic component mounted on a surface thereof;
a molding unit sealing the electronic component and the internal lead;
at least one external lead extending from the internal lead and protruding outwardly from ends of the molding unit; and
a stopper provided on the external lead.

2. The semiconductor package of claim 1, wherein the external lead has a through hole passing through one surface and the other surface thereof.

3. The semiconductor package of claim 2, wherein the stopper fills the through hole and is provided on at least one of one surface and the other surface of the external lead.

4. The semiconductor package of claim 1, wherein the stopper is formed to surround a remainder of the external lead with the exception of a portion thereof mounted in an external substrate.

5. The semiconductor package of claim 1, wherein the stopper is formed of the same material as the molding unit.

6. The semiconductor package of claim 1, wherein the stopper is formed of one of a silicon gel, an epoxy molding compound (EMC), and polyimide.

7. The semiconductor package of claim 1, wherein the stopper connects at least two of the external leads.

8. A method of manufacturing a semiconductor package, the method comprising:
mounting an electronic component on one surface of an internal lead of a lead frame;
placing the lead frame on which the electronic component is mounted in a mold;
forming a molding unit by injecting molding resin into the mold such that the electronic component and the internal lead are sealed and an external lead extending from the internal lead is exposed to the outside; and
forming a stopper on the external lead such that a predetermined space is maintained between the external lead and a substrate into which the external lead is inserted.

9. The method of claim 8, wherein the forming of the molding unit includes:
injecting the molding resin into a first cavity provided in the mold; and
hardening the molding resin injected into the first cavity.

10. The method of claim 8, wherein the forming of the stopper is simultaneously performed with the forming of the molding unit.

11. The method of claim 8, wherein the forming of the stopper on the external lead is performed by placing the external lead in a second cavity provided in the mold and injecting the molding resin into the second cavity.

12. The method of claim 11, wherein the injecting of the molding resin into the second cavity is performed via a second inflow path that connects the first cavity and the second cavity.

13. A semiconductor package manufacturing mold comprising:
a first cavity in which an internal lead having an electronic component mounted thereon is disposed;
a second cavity in which an external lead extending from the internal lead is disposed;
a first inflow path connected to the first cavity so that molding resin is injected into the first cavity; and
a second inflow path connecting the first cavity and the second cavity.
